(19) United States
(12) Patent Application Publication
(10) Pub. No.: US 2008/0064212 A1
(43) Pub. Date: Mar. 13, 2008

(54) Method of manufacturing semiconductor device

(76) Inventors: Yoshihiro Ogawa, Yokohama-Shi (JP); Masahiro Kiyotoshi, Sagamihara-Shi (JP); Katsuhiko Tachibana, Yokkaichi-Shi (JP); Hiroyasu Iimori, Yokohama-Shi (JP); Hiroaki Yamada, Yokohama-Shi (JP); Kaori Umezawa, Kamakura-Shi (JP); Hiroshi Tomita, Yokohama-Shi (JP); Atsuko Kawasaki, Yokohama-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/892,634

(22) Filed: Aug. 24, 2007

(30) Foreign Application Priority Data
Aug. 25, 2006 (JP) 2006-228704
Aug. 2, 2007 (JP) 2007-201855

(51) Int. Cl. H01L 21/311; H01L 21/31

(52) U.S. Cl. 438/694; 438/789; 257/E21.24; 257/E21.249

(57) ABSTRACT

A method of manufacturing a semiconductor device, has applying perhydro polysilazane to a substrate; and immersing at least the surface of said substrate to which perhydro polysilazane is applied in a mixture containing water heated to 120 degrees C. or higher to which ultrasound is applied, thereby modifying the perhydro polysilazane into silicon oxide.

### CROSS-REFERENCE TO RELATED APPLICATIONS

This application is based upon and claims the benefit of priority from the prior Japanese Patent Application No. 2006-228704, filed on Aug. 25, 2006, and No. 2007-201855, filed on Aug. 2, 2007, the entire contents of which are incorporated herein by reference.

### BACKGROUND OF THE INVENTION

1. Field of the Invention

The present invention relates to a method of removing impurities from a silicon oxide film (a spin on glass (SOG) film) used in a device isolation step, an interlayer insulating film formation step and the like of a semiconductor substrate having a fine pattern, and to a method of manufacturing a semiconductor device using the silicon oxide film.

2. Background Art

Conventionally, in a device isolation step of a semiconductor substrate, an SOG film (perhydro polysilazane) has been used as an insulating film for shallow trench isolation (STI) or a pre-metal dielectric (PMD) interlayer insulating film. In these cases, as being well known, after application of perhydro polysilazane, the perhydro polysilazane is stabilized by modifying the perhydro polysilazane into a silicon oxide film by annealing the perhydro polysilazane in an H₂O atmosphere.

The smaller the device, the stricter the constraints on the manufacture of the device, such as those concerning the thermal diffusion and the increase in thickness of the oxide film (bird's beaks), becomes. Therefore, it is difficult to achieve a temperature or processing duration enough to sufficiently modify and stabilize perhydro polysilazane.

And if the applied perhydro polysilazane is not sufficiently stabilized, the perhydro polysilazane is oxidized by the action of water vapor in the air or the like.

As a result, for example, in the following CMP step, the degree of etching varies with time, or the rate of etching using diluted hydrogen fluoride (DHF) or buffered hydrogen fluoride (BHF) varies with time. Thus, there arises a problem that stable device characteristics cannot be obtained.

According to a conventional semiconductor manufacturing method, an SOG film containing polysilazane is cured using an oxidant solution and then modified into a silicon oxide film by one or more thermal processings (see Japanese Patent Laid-Open Publication No. 2005-45230, for example).

According to this conventional technique, the silicon oxide film is stabilized by cleaning using an H₂O₂ solution, which is supposed to be SC1 (hydrogen peroxide+ammonium hydroxide), as the oxidant solution.

However, since ammonia is volatile, and the apparatus is not designed to be heated to a temperature higher than the boiling point of water, the processing using the SC1 as the oxidant solution has to be performed at a temperature equal to or lower than 100 degrees Celsius (° C.).

The stability of the silicon oxide film depends on the temperature of the H₂O₂ solution and the duration of the processing using the solution. For example, there is a problem that the sufficient stability cannot be achieved within the processing time that is practically possible in the conventional technique described above.

For thin film transistor (TFT) liquid crystal displays, insulating films, including a base film, a gate insulating film and an interlayer dielectric (ILD) film, need to be formed at low temperature. However, if perhydro polysilazane is used for such films, it is difficult to form an oxide film of high quality at low temperature, compared with a plasma-enhanced-CVD film.

### SUMMARY OF THE INVENTION

According one aspect of the present invention, there is provided: a method of manufacturing a semiconductor device, comprising applying perhydro polysilazane to a substrate; and immersing at least the surface of said substrate to which perhydro polysilazane is applied in a mixture containing water heated to 120 degrees C. or higher to which ultrasound is applied, thereby modifying the perhydro polysilazane into silicon oxide.

### BRIEF DESCRIPTION OF THE DRAWINGS

FIG. 1 is a diagram showing a configuration of essential parts of a semiconductor manufacturing apparatus according to a First Embodiment of the present invention;

FIG. 2A is a graph showing relationships between the water concentration of a sulfuric acid aqueous solution and the etching selectivity of the silicon oxide film processed with the sulfuric acid aqueous solution;

FIG. 2B is a graph showing a relationship between the power of ultrasound and the flat band voltage;

FIG. 3 is a flowchart showing a method of manufacturing a semiconductor device according to the Second Embodiment, which is an aspect of the present invention, in which the method of removing impurities from a silicon oxide film is applied to a device isolation step;

FIG. 4 is a flowchart showing a method of manufacturing a semiconductor device according to the Third Embodiment, which is an aspect of the present invention, in which the method of removing impurities from a silicon oxide film is applied to a device isolation step;

FIG. 5 is a graph showing relationships between the temperature of steam oxidation and the flat band voltage and between the temperature of steam oxidation and the nitrogen concentration;

FIG. 6 is a graph showing a relationship between the temperature of steam oxidation (degrees C., 1000/absolute temperature K) and the thickness of the thermally grown oxide film (silicon oxide film);

FIG. 7 is a cross-sectional view of a semiconductor device used in a TFT liquid crystal display according to the Fourth Embodiment, which is an aspect of the present invention;

FIG. 8A is a diagram showing an example of a process of manufacturing a cell array part of a NAND flash memory;

FIG. 8B is a diagram showing an example of a process of manufacturing a cell array part of a NAND flash memory;

FIG. 8C is a diagram showing an example of a process of manufacturing a cell array part of a NAND flash memory;

FIG. 8D is a diagram showing an example of a process of manufacturing a cell array part of a NAND flash memory;

FIG. 8E is a diagram showing an example of a process of manufacturing a cell array part of a NAND flash memory; and

FIG. 8F is a diagram showing an example of a process of manufacturing a cell array part of a NAND flash memory.

### DETAILED DESCRIPTION

For example, a method of removing impurities from a silicon oxide film according to an aspect of the present invention is applied to cases where perhydro polysilazane is used as a buried layer for STI or a pre-metal dielectric (PMD) interlayer insulating film in a device isolation step of a semiconductor substrate and where a silicon oxide film is formed at low temperature in a liquid crystal manufacturing process.

The method of removing impurities from a silicon oxide film according to the aspect of the present invention involves immersing the semiconductor substrate in a mixture of sulfuric acid and H₂O at a temperature of 120 degrees C. or higher to which ultrasound is applied after application of perhydro polysilazane or annealing in an H₂O atmosphere or the like.

According to the present invention, the hot water processing at a high temperature of 120 degrees C. or higher involving ultrasound application allows modification of the perhydro polysilazane into a more stable silicon oxide film whose etching rate is less variable.

If the silicon oxide film is used as a gate oxide film of a MOS transistor, for example, variations in thickness of the gate insulating film at the pattern edge (bird's beaks) are reduced.

In particular, since sulfuric acid has an effect of oxidizing the surface of silicon nitride, etching of silicon nitride is prevented from progressing, unlike the case of a processing using a mixture of H₃PO₄ and H₂O.

In the following, embodiments of the present invention will be described with reference to the drawings.

### FIRST EMBODIMENT

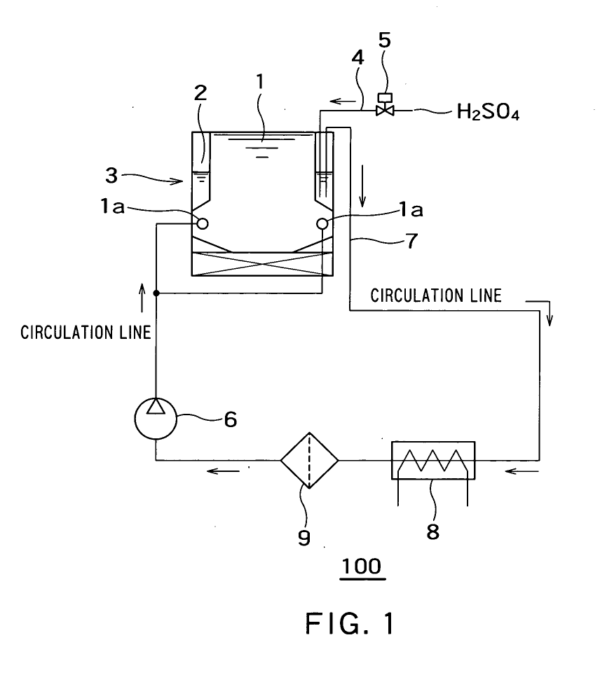

FIG. 1 is a diagram showing a configuration of essential parts of a semiconductor manufacturing apparatus according to a First Embodiment of the present invention.

As shown in FIG. 1, a semiconductor manufacturing apparatus 100 has a cleaning tank 3 that has an inner tank 1 and an outer tank 2 and stores a processing liquid (H₂SO₄+H₂O) in which a semiconductor wafer (substrate) is to be immersed, chemical feeding piping 4 for feeding H₂SO₄ connected to the outer tank 3, and a valve 5 that is disposed on the chemical feeding piping 4 for controlling the amount of feeding of H₂SO₄.

Furthermore, the semiconductor manufacturing apparatus 100 has circulation piping 7 that interconnects the inner tank 1 and the outer tank 2 and includes a pump for circulating the processing liquid from the outer tank 2 to the inner tank 1, a heater 8 that is disposed on the circulation piping 7 for heating the processing liquid to a predetermined temperature, a filter 9 that is included in the circulation piping 7 for removing particles or the like from the processing liquid, and an ultrasound generator 10 for applying ultrasound to the processing liquid stored in the inner tank 1.

The inner tank 1 has a predetermined volume enough for immersion of the semiconductor wafer, and the processing liquid circulated through the circulation piping 7 is fed into the inner tank 1 through an outlet 1a.

Then, the stored processing liquid overflows from the inner tank 1. When the surface of the processing liquid in the outer tank 2 reaches a certain height, the circulation pump is activated to start chemical circulation. Thus, a first liquid surface height, which is the height of the processing liquid in the inner tank 1, is kept constant.

Furthermore, the temperature of the processing liquid is kept at a predetermined temperature through the control of the heater 8. Furthermore, the power of the ultrasound applied to the processing liquid is controlled by the ultrasound generator 10.

Cleaning of the semiconductor wafer is carried out by immersing the semiconductor wafer in the processing liquid.

The outer tank 2 has a predetermined volume and receives the processing liquid that has overflowed from the inner tank 1 as described above. In addition, H₂SO₄ is fed into the outer tank 2 as required.

Table 1 shows a relationship between the concentration of sulfuric acid in the processing liquid and the boiling point of the processing liquid.

TABLE 1

| H₂SO₄ | boiling |
|---|---|
| (%) | point (° C.) |
| 0 | 100 |
| 2.08 | 100.3 |
| 10.77 | 101.7 |
| 19.89 | 103.9 |
| 29.53 | 107.3 |
| 39.92 | 113.6 |
| 45.35 | 118.2 |
| 48.1 | 121.2 |
| 50.87 | 124.6 |
| 59.82 | 138.4 |
| 68.13 | 159.2 |
| 79.43 | 200.6 |
| 85.66 | 230.7 |
| 90.6 | 259 |
| 95 | 297 |
| 98 | 327 |

As shown in Table 1, the boiling point of the mixture varies according to the mixing ratio of H₂SO₄ and H₂O.

Therefore, at atmospheric pressure, for example, in order to achieve a boiling point of the mixture liquid of about 120 degrees C. or higher, the sulfuric acid concentration has to be at least about 45% or higher.

In order to carry out the processing stably at constant temperature and concentration, the semiconductor manufacturing apparatus 100 further has a mechanism for feeding pure water to keep the boiling point constant.

Now, there will be discussed a result of etching, using DHF, of the silicon oxide film made from perhydro polysilazane by the processing according to this embodiment.

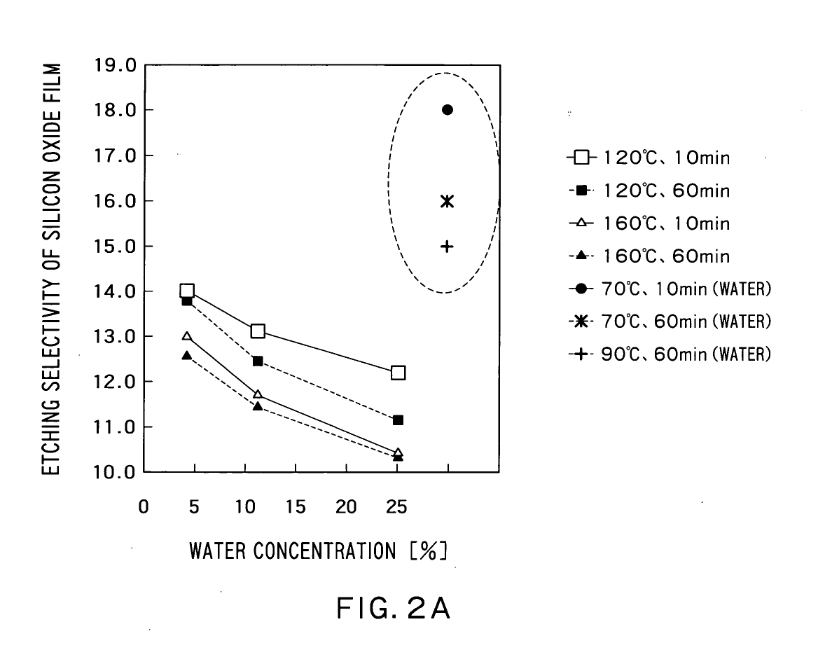

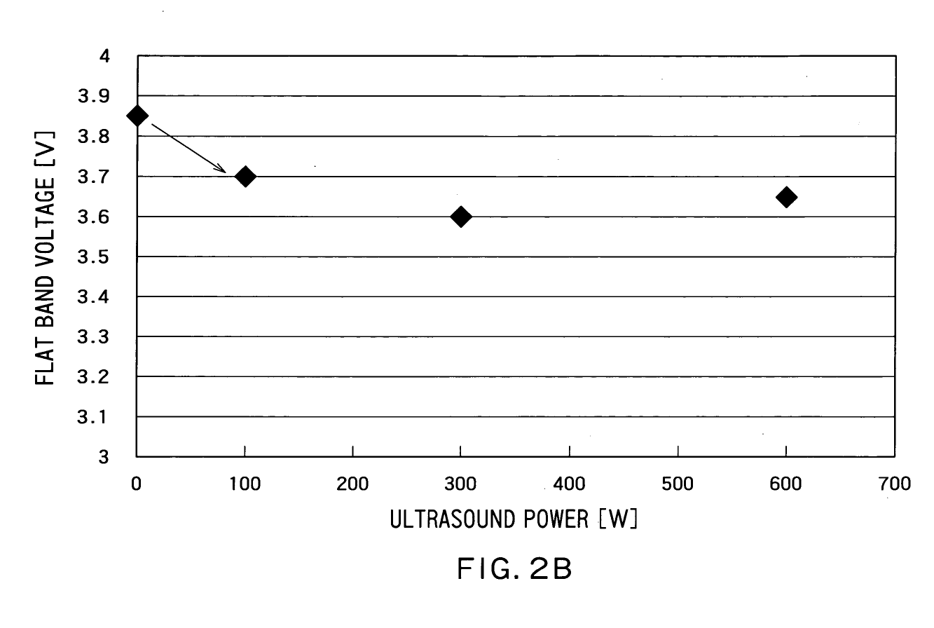

FIG. 2A is a graph showing relationships between the water concentration of a sulfuric acid aqueous solution and the etching selectivity of the silicon oxide film processed with the sulfuric acid aqueous solution.

As shown in FIG. 2A, the higher the processing temperature, and the higher the water concentration (or the lower the sulfuric acid concentration), the lower the selectivity of etching (the amount of etching), using DHF, of the thermally grown silicon oxide film formed from perhydro polysilazane by the processing according to this embodiment becomes.

In other words, it can be considered that the higher the processing temperature, and the higher the water concentration (or the lower the sulfuric acid concentration), the more efficiently the modification of perhydro polysilazane progresses.

As shown in FIG. 2A, if the immersion processing is carried out at a processing temperature of 120 degrees C. or higher and at a water concentration of 4% or higher (at a sulfuric acid concentration of 96% or lower), the selectivity is lower than that in the case of the immersion processing using water at a temperature of 90 degrees C. or lower, and the silicon oxide film has better quality with stability.

In particular, to obtain a silicon oxide film of better quality, the processing temperature is preferably equal to or higher than 160 degrees C., and the water concentration is preferably equal to or higher than 20% (the sulfuric acid concentration is equal to or lower than 80%).

From the viewpoint of suppression of etching of silicon nitride, sulfuric acid is preferable as the material to be mixed with water as described above. However, a solvent other than sulfuric acid can also be used to raise the boiling point of H₂O to 120 degrees C. or higher.

Now, there will be discussed a result of measurement of the flat band voltage after immersion of the silicon oxide film in water to which ultrasound is applied.

FIG. 2B is a graph showing a relationship between the power of ultrasound and the flat band voltage.

In FIG. 2B, the frequency of the ultrasound varies within a range of 750 kHz to 2 MHz.

As shown in FIG. 2B, the flat band voltage is lower in the case where ultrasound is applied than in the case where no ultrasound is applied. In other words, application of ultrasound causes reduction of the amount of nitrogen remaining in the silicon oxide film and reduction of the amount of fixed charges that degrade the transistor characteristics.

In general, if ultrasound is applied to a liquid, cavitation occurs, and particles on the semiconductor surface are removed. At the same time, particles on the pattern can be removed.

The flat band voltage described above is used as a simple indicator of fixed charges in an insulating film. A potential difference occurs between a gate electrode material and silicon in order to make the Fermi levels thereof match with each other due to the effect of the difference in work function or the fixed charges localized at the interface between the insulating film and the silicon substrate. The applied gate voltage required to cancel the potential difference is referred to as flat band voltage. If the flat band voltage is high, it can be considered that a large amount of fixed charges is localized at the interface between the insulating film and the silicon substrate.

If there are fixed charges in the insulating film buried for STI, the electrical field produced by the fixed charges in the STI is effectively applied even if no gate voltage is applied to the transistor.

As a result, the transistor is turned on at a low voltage, and the amount of off leakage current increases. In addition, when there are fixed charges at the bottom of the STI, if the anti-inversion ion implantation concentration at the bottom of the STI is low, the STI itself constitutes a large transistor.

Thus, for example, there arises a problem that, when a voltage is applied to wiring on the STI, inversion occurs at the bottom of the STI, and the diffusion layers, which would otherwise be separated by the STI, cannot be insulated from each other.

As described above, the amount of fixed charges that degrade the transistor characteristics is reduced by applying ultrasound.

In this way, the semiconductor wafer with perhydro polysilazane applied thereto is immersed in the processing liquid (a mixture containing water) heated to 120 degrees C. or higher to which ultrasound is applied, thereby modifying the perhydro polysilazane into silicon oxide. Thus, a silicon oxide film of better quality that improves the transistor characteristics can be formed.

According to this embodiment, the boiling point of the mixture is controlled to be constant. However, the immersion processing can be performed using H₂O even at a temperature lower than the boiling point, if the temperature is equal to or higher than 120 degrees C. For example, the inner tank 1 for the immersion processing can be placed in an enclosed space, and the boiling point of H₂O can be controlled to be equal to or higher than 120 degrees C. by controlling the pressure in the space.

As described above, according to the method of manufacturing a semiconductor device according to this embodiment, the etching rate of the silicon oxide film can be stabilized, and more stable device performance can be achieved.

### SECOND EMBODIMENT

In the First Embodiment, there has been described an example of a method of removing impurities from a silicon oxide film that is applied to a method of manufacturing a semiconductor device.

In a Second Embodiment, there will be described a method of manufacturing a semiconductor device in which the method of removing impurities from a silicon oxide film is applied to a device isolation step.

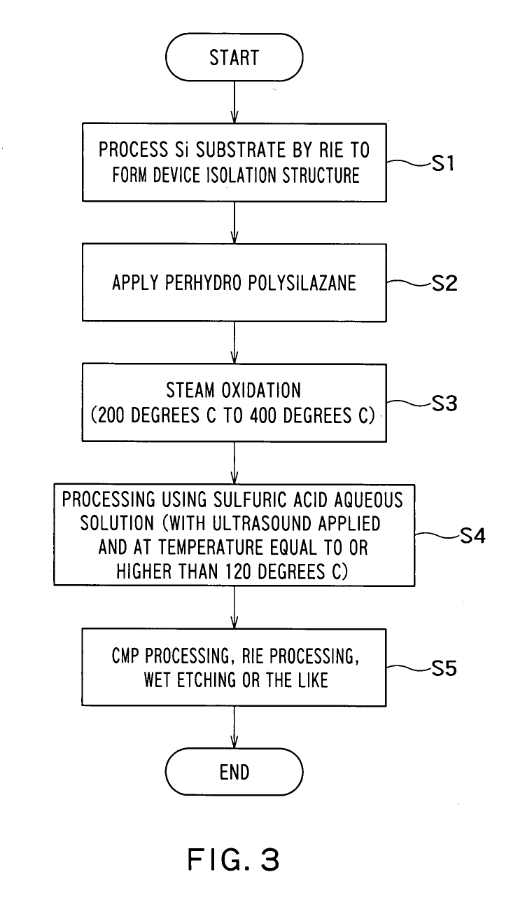

FIG. 3 is a flowchart showing a method of manufacturing a semiconductor device according to the Second Embodiment, which is an aspect of the present invention, in which the method of removing impurities from a silicon oxide film is applied to a device isolation step.

The method of removing impurities from a silicon oxide film in the Second Embodiment is implemented by the same semiconductor manufacturing apparatus as in the First Embodiment.

As shown in FIG. 3, first, in a device isolation step of a semiconductor device, an STI structure is formed in a semiconductor substrate (silicon substrate) by reactive ion etching (RIE) (step S1).

Then, perhydro polysilazane is applied to the semiconductor substrate having the STI structure by spin coating, for example (step S2).

Then, to modify perhydro polysilazane into oxide silicon, steam oxidation at a temperature of 200 degrees C. to 400 degrees C. is carried out (step S3). In this step, the perhydro polysilazane film is modified into a silicon oxide film containing about 2% of silicon and containing about 1% of nitrogen (N) and several hundreds ppm of carbon (C) as impurities.

Then, at least the surface of the semiconductor substrate to which perhydro polysilazane is applied, is immersed in a sulfuric acid aqueous solution heated to 120 degrees C. or higher to which ultrasound is applied, thereby raising the degree of the modification into silicon oxide (step S4).

As a result, as shown in Table 2, the amount of impurities in the modified silicon oxide film is reduced. Since the amount of nitrogen and carbon, which are impurities, is reduced, the amount of substances that cause fixed charges is reduced. Thus, the fixed charge density is improved from 1×10¹¹ C/cm² to 4×10¹⁰ C/cm².

In addition, the amount of excessive silicon, which tends to react with water vapor in the air and cause a temporal change of the film characteristics, is reduced, so that the silicon oxide film is further stabilized.

TABLE 2

| impurity | carbon | nitrogen | silicon |
|---|---|---|---|
| before processing | 600 ppm | 1.0% | 2.0% |
| according to this | | | |
| embodiment | | | |
| after processing | 80 ppm | 0.1% | 0.1% |
| according to this | | | |
| embodiment | | | |

Following the step S4, the processed semiconductor substrate is planarized by CMP, or the height of the STI structure is adjusted to a desired height by RIE using SiO₂ or wet etching using DHF or BHF, thereby achieving device isolation (step S5).

Alternatively, following the formation of the STI structure in the step S1, a silicon nitride film or CVD oxide film may be deposited before application of perhydro polysilazane, thereby improving the adhesion between the STI structure and the applied insulating film (perhydro polysilazane) or suppressing damage to the gate oxide film during a thermal step.

Alternatively, following the application of perhydro polysilazane, a plasma-enhanced-CVD oxide film or the like may be deposited to form an STI structure composed of a multilayer insulating film composed of an organic coating film and a CVD insulating film.

In the case where the steam oxidation is performed at a lower temperature or in a shorter time or where the steam oxidation is omitted, if the processing is performed using a sulfuric acid aqueous solution at a high temperature, the reaction can progress abruptly to cause fracture of a film.

Therefore, in such a case, it is preferred that the hot water processing or the processing using the sulfuric acid aqueous solution is carried out stepwise at two different temperatures while applying ultrasound, or the processing using the sulfuric acid aqueous solution is carried out by raising stepwise the temperature of the mixture from a temperature equal to or lower than 100 degrees C. to a temperature equal to or higher than 120 degrees C. while applying ultrasound, thereby making the modification into the silicon oxide film progress stepwise.

Furthermore, in the case where the steam oxidation is omitted, since the perhydro polysilazane film is likely to be dissolved in the sulfuric acid aqueous solution, a bake processing may be carried out instead of the steam oxidation. The bake processing is preferably carried out at a temperature of 250 degrees C. or higher.

As described above, according to the method of manufacturing a semiconductor device according to this embodiment, the etching rate of the silicon oxide film can be stabilized, and more stable device performance can be achieved.

### THIRD EMBODIMENT

In the Second Embodiment, there has been described a method of manufacturing a semiconductor device in which the method of removing impurities from a silicon oxide film is applied to a device isolation step.

In a Third Embodiment, there will be described another example of the method of manufacturing a semiconductor device in which the method of removing impurities from a silicon oxide film is applied to a device isolation step.

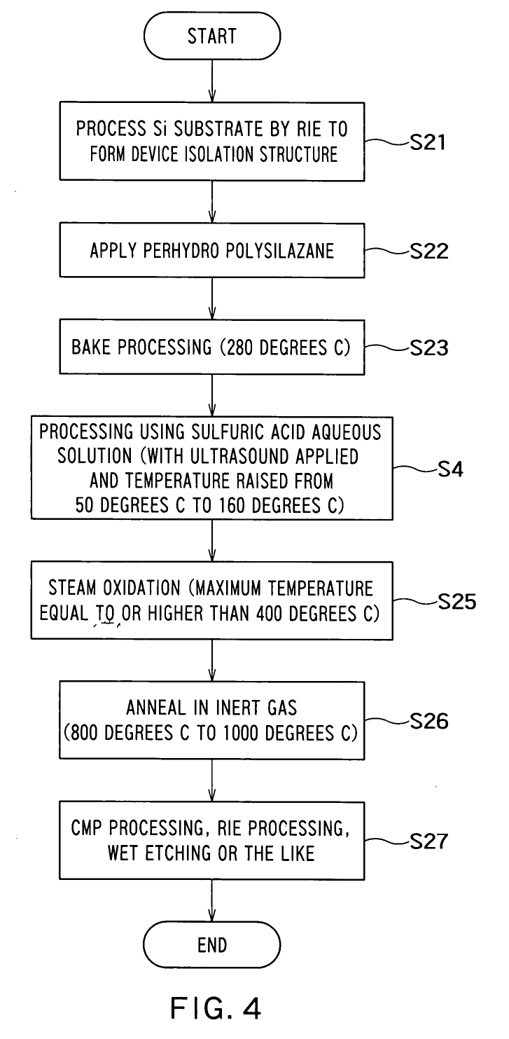

FIG. 4 is a flowchart showing a method of manufacturing a semiconductor device according to the Third Embodiment, which is an aspect of the present invention, in which the method of removing impurities from a silicon oxide film is applied to a device isolation step.

The method of removing impurities from a silicon oxide film in the Third Embodiment is implemented by the same semiconductor manufacturing apparatus as in the First Embodiment.

As shown in FIG. 4, first, in a device isolation step of a semiconductor device, an STI structure is formed in a semiconductor substrate (silicon substrate) by reactive ion etching (step S21).

Then, perhydro polysilazane is applied to the semiconductor substrate having the STI structure by spin coating, for example (step S22).

Then, the applied perhydro polysilazane is baked (at 280 degrees C., for example), thereby increasing the resistance of the perhydro polysilazane film to the sulfuric acid aqueous solution (step S23).

Then, at least the surface of the semiconductor substrate to which perhydro polysilazane is applied is immersed in hot water or a sulfuric acid aqueous solution at a temperature equal to or lower than 100 degrees C. to which ultrasound is applied and then immersed in a sulfuric acid aqueous solution heated to 120 degrees C. or higher to which ultrasound is applied (step S24). In this embodiment, for example, the temperature of a sulfuric acid aqueous solution having a sulfuric acid concentration of 80% is raised from 50 degrees C. to 160 degrees C. at a rate of 5 degrees per minute, and the substrate with perhydro polysilazane applied thereto is immersed in the sulfuric acid aqueous solution.

Alternatively, in the step S24, at least the surface of the semiconductor substrate to which perhydro polysilazane is applied may be immersed in a sulfuric acid aqueous solution at a temperature lower than 120 degrees C. to which ultrasound is applied, and then the temperature of the sulfuric acid aqueous solution to which ultrasound is applied may be raised to a temperature equal to or higher than 120 degrees C. For example, the substrate is immersed for 20 minutes in a sulfuric acid aqueous solution having a sulfuric acid concentration of 80% at 100 degrees C. to which ultrasound is applied, and then immersed for 40 minutes in a sulfuric acid aqueous solution having a sulfuric acid concentration of 80% at 160 degrees C. to which ultrasound is applied.

In the step S24, ultrasound need only to be applied to the sulfuric acid aqueous solution when at least the surface of the semiconductor substrate to which perhydro polysilazane is applied is immersed in the sulfuric acid aqueous solution heated to 120 degrees C. or higher.

In the step S24, perhydro polysilazane is modified into silicon oxide.

Then, following the step S24, the surface of the semiconductor substrate is subjected to steam oxidation (step S25). In this step, the amount of nitrogen remaining in the silicon oxide film is reduced by steam oxidation at a maximum temperature of 400 degrees C. or higher.

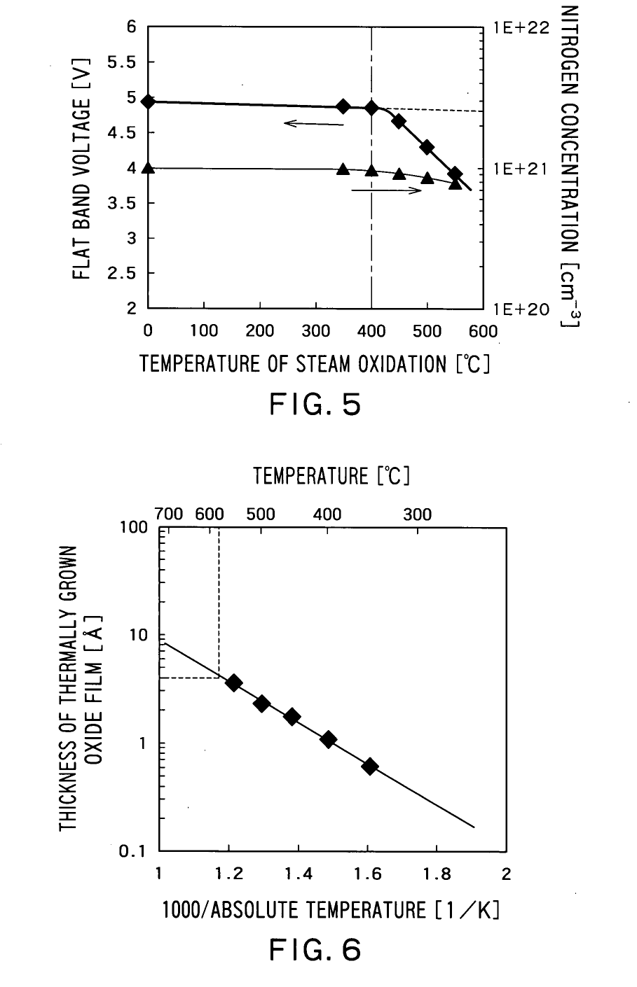

FIG. 5 is a graph showing relationships between the temperature of steam oxidation and the flat band voltage and between the temperature of steam oxidation and the nitrogen concentration.

As shown in FIG. 5, if the steam oxidation is carried out at a temperature equal to or higher than 400 degrees C., the amount of nitrogen remaining in the silicon oxide film is reduced, and the amount of fixed charges that degrade the transistor characteristics is reduced.

FIG. 6 is a graph showing a relationship between the temperature of steam oxidation (degrees C., 1000/absolute temperature K) and the thickness of the thermally grown oxide film (silicon oxide film).

As shown in FIG. 6, if the steam oxidation is carried out at a temperature equal to or higher than 600 degrees C., oxidation of the semiconductor substrate (silicon substrate) during stream oxidation cannot be ignored (specifically, the substrate is oxidized to a depth equal to or more than one atomic layer (0.4 nm)).

The silicon oxide film can be further stabilized and improved in processing tolerance by raising the temperature of steam oxidation. However, for the reason described above, the maximum temperature is preferably equal to or lower than 600 degrees C.

Following the steam oxidation in the step S25, annealing is carried out in an inert gas atmosphere at 800 degrees C. to 1000 degrees C. (step S26). In this way, burying of the silicon oxide film of high quality for STI is completed.

Then, the semiconductor substrate is planarized by CMP, or the height of the STI structure is adjusted to a desired height by RIE using SiO₂ or wet etching using DHF or BHF, thereby achieving device isolation (step S27).

Alternatively, following the formation of the STI structure, a silicon nitride film or chemical vapor deposition (CVD) oxide film may be deposited before application of perhydro polysilazane, thereby improving the adhesion between the STI structure and the applied insulating film or suppressing damage to the gate oxide film during a thermal step.

Alternatively, following the application of perhydro polysilazane, a plasma-enhanced-CVD oxide film or the like may be deposited to form an STI structure composed of a multilayer insulating film composed of an organic coating film and a CVD insulating film.

As described above, according to the method of manufacturing a semiconductor device according to this embodiment, the etching rate of the silicon oxide film can be stabilized, and more stable device performance can be achieved.

### FOURTH EMBODIMENT

In the First Embodiment, there has been described a method of removing impurities from a silicon oxide film that is applied to a method of manufacturing a semiconductor device.

In a Fourth Embodiment, in particular, there will be described an example in which the method of removing impurities from a silicon oxide film is used for a silicon oxide film of a semiconductor device used in a TFT liquid crystal display.

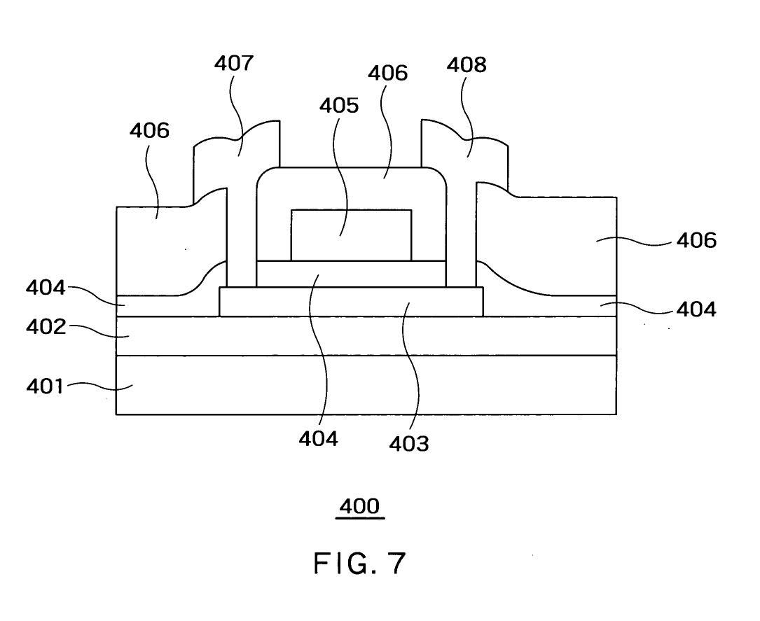

FIG. 7 is a cross-sectional view of a semiconductor device used in a TFT liquid crystal display according to the Fourth Embodiment, which is an aspect of the present invention. The method of removing impurities from a silicon oxide film according to the Fourth Embodiment is implemented by the same semiconductor manufacturing apparatus as in the First Embodiment.

As shown in FIG. 7, first, perhydro polysilazane is applied to the entire surface of a glass substrate 401 and baked at 280 degrees C., and then the glass substrate 401 is immersed in a sulfuric acid aqueous solution heated to 120 degrees C. or higher to which ultrasound is applied, thereby modifying the perhydro polysilazane into a silicon oxide film (SiO₂) 402.

Then, amorphous silicon 403 is deposited on the glass substrate 401 and patterned.

Then, perhydro polysilazane is applied to the glass substrate 401 and baked at 280 degrees C., and then the glass substrate 401 is immersed in a sulfuric acid aqueous solution heated to 120 degrees C. or higher to which ultrasound is applied, thereby modifying the perhydro polysilazane into a silicon oxide film 404.

Then, a gate electrode film 405 is formed and patterned. Then, perhydro polysilazane is applied to the glass substrate 401 and baked at 280 degrees C., and then the glass substrate 401 is immersed in a sulfuric acid aqueous solution heated to 120 degrees C. or higher to which ultrasound is applied, thereby modifying the perhydro polysilazane into a silicon oxide film 406.

Finally, wirings 407 and 408 are formed to complete a transistor 400 of a TFT liquid crystal display.

According to this embodiment, an oxide film of high quality can be formed at low temperature, so that the characteristics of the transistor are improved.

Table 3 shows the concentrations of carbon remaining in the silicon oxide film of the transistor and the threshold voltage thereof.

For comparison, Table 3 shows the concentrations of carbon remaining in a plasma-enhanced-CVD tetraethylorthosilicate (TEOS) oxide film (A) and an oxide film formed by modifying perhydro polysilazane with an amine additive at low temperature (equal to or lower than 300 degrees C.) (B) and the threshold voltages of transistors with those silicon oxide films.

TABLE 3

| | | threshold voltage |
|---|---|---|
| | remaining carbon | (100-nm-thick gate |
| | concentration [cm⁻³] | oxide film) |
| this | 1.0 × 10¹⁹ | −1.2 V |
| embodiment | | |
| (A) | 3.2 × 10¹⁹ | −2.5 V |
| (B) | 1.5 × 10²⁰ | −4 V |

As can be seen from Table 3, according to the method of manufacturing a semiconductor device according to this embodiment, perhydro polysilazane can be modified into a silicon oxide film at low temperature (equal to or lower than 300 degrees C.) without introducing amine, which tends to leave carbon in the film as an impurity.

That is, according to the method of manufacturing a semiconductor device according to this embodiment, it is possible to form a silicon oxide film of better quality at low temperature than plasma-enhanced CVD, which tends to leave carbon in the film.

As described above, according to the method of manufacturing a semiconductor device according to this embodiment, the etching rate of the silicon oxide film can be stabilized, and more stable device performance can be achieved.

### FIFTH EMBODIMENT

According to a Fifth Embodiment described below, the method of forming a silicon oxide film described above is applied to a method of forming a device isolation film for a cell array part of a NAND flash memory.

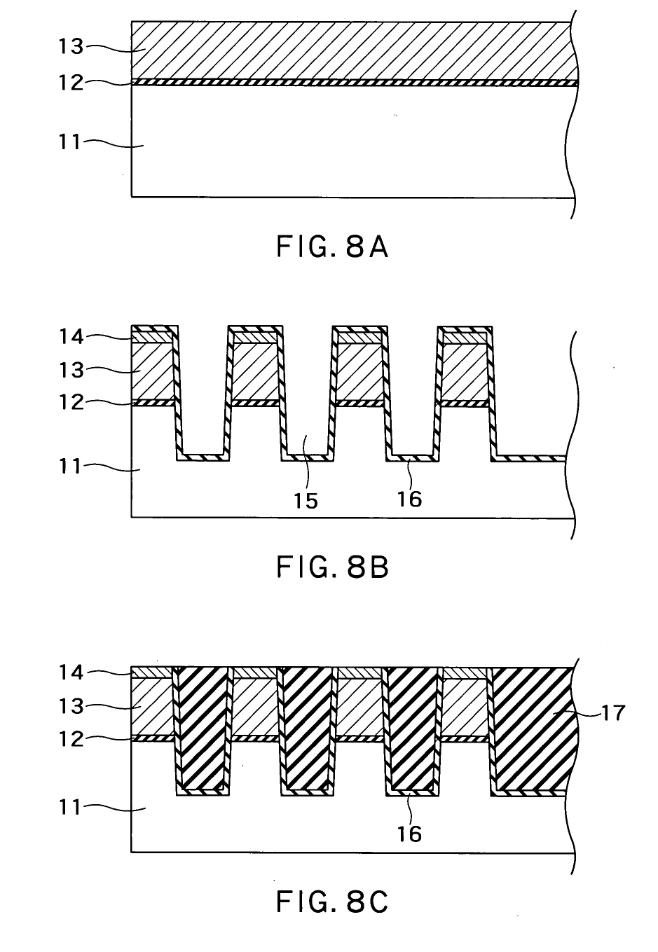

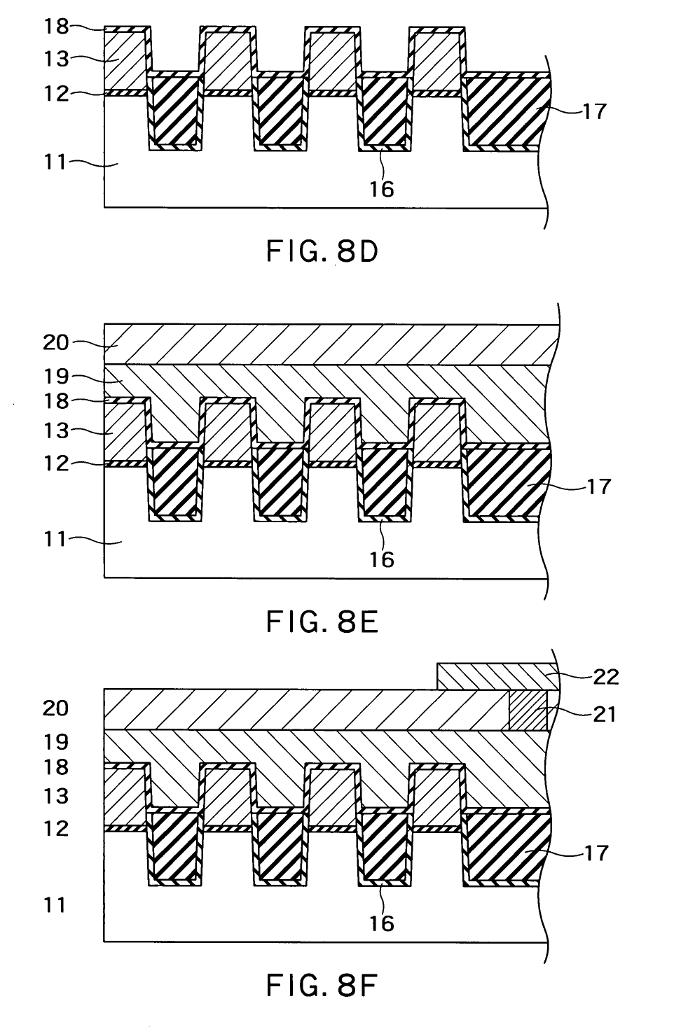

FIGS. 8A to 8F are diagrams showing an example of a process of manufacturing a cell array part of a NAND flash memory. A gate oxide film 12 is formed on a semiconductor substrate 11, and a charge storage layer 13 of polysilicon is formed on the gate oxide film 12 (FIG. 8A).

Then, a mask layer 14 is formed on the charge storage layer 13, and then, a trench 15 for device isolation is formed by lithography and reactive ion etching. Then, a liner layer 16 is formed on the upper surface of substrate including the inner wall of the trench 15 (FIG. 8B).

Then, a polysilazane film is deposited in the trench 15 and modified into a silicon oxide film, thereby forming a device isolation region 17 (FIG. 8C). This step will be described in detail below.

First, perhydro silazane polymer [(SiH₂NH)ₙ] having an average molecular weight of 3000 to 6000 is dispersed in xylene, dibutyl ether or the like to form a perhydro silazane polymer solution, and the perhydro silazane polymer solution is applied to the surface of the semiconductor substrate 11 by spin coating. The application of liquid has an advantage that any narrow isolation groove can be filled with perhydro silazane polymer without any void or seam.

For example, the spin coating is performed under conditions that the rotational speed of the semiconductor substrate 11 is 1200 rpm, the rotation duration is 300 seconds, the amount of the perhydro silazane polymer solution is 2 cc, and the target coating thickness immediately after baking is 450 nm.

Then, the semiconductor substrate 11 with the coating formed thereon is heated to 150 degrees C. on a hot plate and baked for 3 minutes in an inert gas atmosphere, thereby volatilizing the solvent of the perhydro silazane polymer solution. At this point, the coating contains about several to a dozen or so percent of carbon or carbon hydride from the solvent as an impurity. Thus, at this point, the perhydro polysilazane film is close to a low-density silicon nitride film containing a solvent residue.

The perhydro polysilazane film is subjected to reduced-pressure steam oxidation for 30 minutes in a reduced-pressure atmosphere at a temperature of 200 to 300 degrees C. and a pressure of 600 Torr or lower. This step is intended to make the polysilazane film more susceptible to reaction with a high-temperature sulfuric acid aqueous solution according to the present invention.

Then, the polysilazane film is oxidized by high-temperature sulfuric acid aqueous solution processing. In this step, the polysilazane film is immersed in the sulfuric acid aqueous solution heated to 120 degrees C. or higher to which ultrasound is applied, thereby increasing the degree of modification into silicon oxide.

If moisture absorption is performed using hot water before the high-temperature sulfuric acid aqueous solution processing, the uniformity of the film can be improved. As a result of the high-temperature sulfuric acid aqueous solution, the concentration of carbon (C) in the film is reduced to 1E20 cm⁻³ or lower, and the concentration of nitrogen (N) in the film is reduced to 1E21 cm⁻³ or lower.

Then, the polysilazane film processed with the sulfuric acid aqueous solution is further subjected to reduced-pressure steam oxidation at a temperature of 400 to 600 degrees C., thereby removing carbon and nitrogen remaining in the film. Thus, the concentration of carbon (C) in the film is reduced to 1E20 cm⁻³ or lower, and the concentration of nitrogen (N) in the film is reduced to 1E20 cm⁻³ or lower. Furthermore, the polysilazane film is annealed in an inert gas atmosphere at 800 degrees C. to 1000 degrees C., thereby densifying the polysilazane film.

Then, the polysilazane film is planarized by CMP until the mask layer 14 is exposed. In this way, the device isolation region 17 in the trench 15 is formed (FIG. 8C).

Then, the upper part of the device isolation region 17 is trimmed to make the upper surface of the device isolation region 17 lower than the upper surface of the polysilicon layer. Then, an ONO film 18, which constitutes an inter-electrode insulating film, is formed on the device isolation region 17 and the polysilicon layer (FIG. 8D).

Then, a polysilicon layer 19, which constitutes a control gate electrode, is formed on the ONO film 18. Then, a silicon nitride film 20 is formed on the polysilicon layer 19 (FIG. 8E).

Then, a contact hole 21 is formed in the silicon nitride film 20, and then, a wiring part 22 connected to the contact hole 21 is formed (FIG. 8F).

As described above, according to the Fifth Embodiment, when forming the device isolation film for a cell array part of a NAND flash memory, the polysilazane film in the trench 15 is immersed in a sulfuric acid aqueous solution heated to 120 degrees C. or higher to which ultrasound is applied, thereby increasing the degree of modification of the polysilazane into silicon oxide. Therefore, the silicon oxide film constituting the device isolation film has an improved quality, and the writing/reading performance of the flash memory is improved.

In the Fifth Embodiment, the method of forming the device isolation film for a cell array part of a NAND flash memory has been described. However, the method can be applied to formation of a device isolation film for a peripheral circuit part. Alternatively, the method can be applied to formation of a device isolation film of a NOR flash memory.

What is claimed is:

1. A method of manufacturing a semiconductor device, comprising:
applying perhydro polysilazane to a substrate; and
immersing at least the surface of said substrate to which perhydro polysilazane is applied in a mixture containing water heated to 120 degrees C. or higher to which ultrasound is applied, thereby modifying the perhydro polysilazane into silicon oxide.

2. The method of manufacturing a semiconductor device according to claim 1, wherein said mixture is a sulfuric acid aqueous solution.

3. The method of manufacturing a semiconductor device according to claim 2, wherein the sulfuric acid concentration of said sulfuric acid aqueous solution is equal to or higher than 45% and equal to or lower than 96%.

4. The method of manufacturing a semiconductor device according to claim 1, wherein at least the surface of said substrate to which perhydro polysilazane is applied is immersed in hot water or a sulfuric acid aqueous solution at a temperature lower than 100 degrees C. and then immersed in a sulfuric acid aqueous solution heated to 120 degrees C. or higher to which ultrasound is applied.

5. The method of manufacturing a semiconductor device according to claim 1, wherein a silicon oxide film formed by said modifying is etched by CMP.

6. The method of manufacturing a semiconductor device according to claim 1, wherein a silicon oxide film formed by said modifying is wet-etched with an etchant containing hydrofluoric acid.

7. The method of manufacturing a semiconductor device according to claim 2, wherein before immersing said substrate in said sulfuric acid aqueous solution, the applied perhydro polysilazane is baked.

8. The method of manufacturing a semiconductor device according to claim 3, wherein the duration of the immersion of said substrate in said sulfuric acid aqueous solution is equal to or longer than 5 minutes.

9. The method of manufacturing a semiconductor device according to claim 2, wherein at least the surface of said substrate to which perhydro polysilazane is applied is immersed in a sulfuric acid aqueous solution at a temperature lower than 120 degrees C., and then the temperature of said sulfuric acid aqueous solution is raised to 120 degrees C. or higher, and ultrasound is applied to said sulfuric acid aqueous solution.

10. The method of manufacturing a semiconductor device according to claim 1, wherein after at least the surface of said substrate to which perhydro polysilazane is applied is immersed in said mixture, the surface of said substrate is subjected to steam oxidation.

11. The method of manufacturing a semiconductor device according to claim 10, wherein said steam oxidation is performed at a temperature equal to or higher than 400 degrees C. and equal to or lower than 600 degrees C.

12. The method of manufacturing a semiconductor device according to claim 1, wherein a silicon oxide film formed by said modifying is used as an interlayer insulating film of a semiconductor device.

13. The method of manufacturing a semiconductor device according to claim 1, wherein a silicon oxide film formed by said modifying is used as a device isolation film of a flash memory.
